(19) United States
(12) Patent Application Publication
(10) Pub. No.: US 2026/0107540 A1
(43) Pub. Date: Apr. 16, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Hsien-Chung HUANG, Hsinchu City (TW); Zhi-Chang LIN, Hsinchu County (TW); Tsung-Kai CHIU, Hsinchu County (TW); I-Hung LI, New Taipei City (TW); Chu-Hsuan SHA, Taipei City (TW); Ku-Feng YANG, Hsinchu County (TW); Bing-Hung CHEN, New Taipei City (TW)

(73) Assignee: TAIWAN SEMICONDUCTOR MANUFACTURING COMPANY, LTD., Hsinchu (TW)

(21) Appl. No.: 18/917,189

(22) Filed: Oct. 16, 2024

(51) Int. Cl. H01L 29/66; H01L 29/06; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 64/018

(57) ABSTRACT

A method includes forming a first stack of alternating first semiconductor layers and first sacrificial layers over a substrate and a second stack of alternating second semiconductor layers and second sacrificial layers over the first stack; replacing the first sacrificial layers with dummy interposers, respectively; forming first source/drain epitaxy structures on opposite sides of the first semiconductor layers; forming second source/drain epitaxy structures on opposite sides of the second semiconductor layers; removing the second sacrificial layers and the dummy interposers; and forming a first gate structure wrapping around at least one of the first semiconductor layers and a second gate structure wrapping around at least one of the second semiconductor layers.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

As the semiconductor industry further progresses into technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIGS. 2 to 13 illustrate a method in various stages of forming a semiconductor device in accordance with some embodiments of the present disclosure.

FIGS. 14A and 14B are cross-sectional views of a semiconductor device in accordance with some embodiments of the present disclosure.

FIGS. 15 to 27 illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

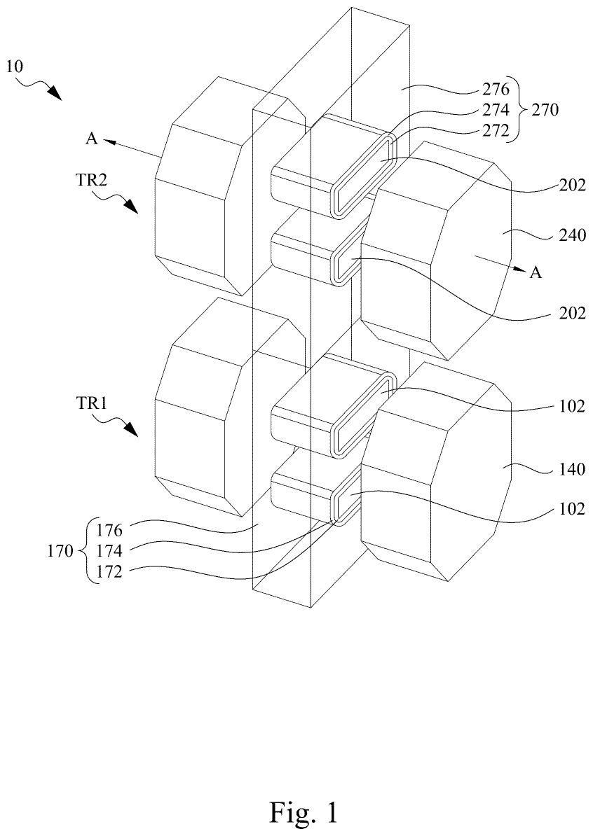

FIG. 1 is a perspective view of a semiconductor device in accordance with some embodiments of the present disclosure. In the present disclosure, a complementary FET (CFET) 10 is provided, and its manufacturing method will be disclosed in the following discussion. In a CFET 10, a first transistor TR1 is disposed over a substrate (not shown), and a second transistor TR2 is disposed vertically above the first transistor TR1. In some embodiments, the first transistor TR1 and the second transistor TR2 may be field effect transistor (FET) and may both include gate-all-around (GAA) configuration, and thus the first transistor TR1 and the second transistor TR2 can also be referred to as GAA FETs. The first transistor TR1 includes first semiconductor channel layers 102 vertically stacked one above another, a first metal gate structure 170 wrapping around each of the first semiconductor channel layers 102, and first source/drain epitaxy structures 140 on opposite ends of each of the first semiconductor channel layers 102. Similarly, the second transistor TR2 includes second semiconductor channel layers 202 vertically stacked one above another, a second metal gate structure 270 wrapping around each of the second semiconductor channel layers 202, and second source/drain epitaxy structures 240 on opposite ends of each of the second semiconductor channel layers 202. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. In some embodiments, the first transistor TR1 has a first conductivity type (e.g., p-type) and the second transistor TR2 has a second conductivity type (e.g., n-type) different from the first conductivity type. In some embodiments, the first transistor TR1 can be referred to as a P-FET, and the second transistor TR2 can be referred to as an N-FET.

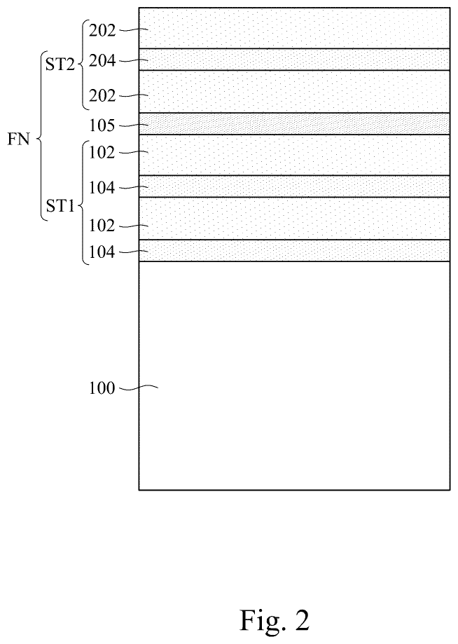

FIGS. 2 to 13 illustrate a method in various stages of forming a semiconductor device in accordance with some embodiments of the present disclosure. It is noted that FIGS. 2 to 13 include cross-sectional views the same as the cross-sectional view taken along line A-A of FIG. 1. Although FIGS. 2 to 13 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2 to 13 may be similar to those described with respect to FIG. 1, and thus relevant details will not be repeated for brevity.

Reference is made to FIG. 2. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A fin structure FN is formed over the substrate 100. The fin structure FN includes a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 40 percent and about 60 percent, and the germanium percentage (atomic percentage concentration) of the semiconductor layers 104 and 204 is in a range from about 20 percent and about 40 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es). In some embodiments, the semiconductor layers 104 and 204 may be removed during a replacement gate (RPG) process, and thus the semiconductor layers 104 and 204 can also be referred to as sacrificial layers.

In some embodiments, the semiconductor layers 102 and 202 may include a vertical height in a range from about 2 nm to about 10 nm. The semiconductor layers 102 and 202 may include a lateral width in a range from about 40 nm to about 70 nm. The semiconductor layers 104 and 204 may include a vertical height in a range from about 2 nm to about 10 nm. In some embodiments, the number of the semiconductor layers 102 may be in a range from about 1 to 1000, and the number of the semiconductor layers 202 may be in a range from about 1 to 1000. In some embodiments, the semiconductor layers 102 and 202 may include a width in a range from about 1 nm to about 8 nm or in a range from about 8 nm to about 300 nm.

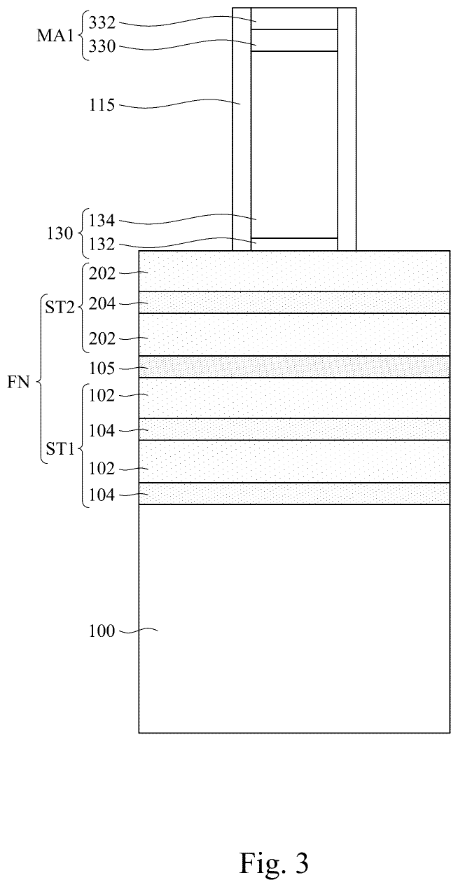

Reference is made to FIG. 3. A dummy gate structure 130 is formed over the substrate 100 and crossing the fin structure FN. In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming a patterned mask MA1 over the dummy gate layer, and then performing an etching process to the dummy dielectric layer and the dummy gate layer by using the patterned mask MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, the patterned mask MA1 includes a first hard mask 330 and a second hard mask 332 over the first hard mask 330. The first hard mask 330 and the second hard mask 332 may be made of different materials. In some embodiments, the first hard mask 330 may be formed of silicon nitride, and the second hard mask 332 may be formed of silicon oxide.

Gate spacers 115 are formed on opposite sidewalls of the dummy gate structure 130. In some embodiments, the gate spacers 115 may be formed of silicon oxide, silicon nitride, silicon oxynitride, combinations thereof. In some embodiments, the gate spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structure 130. In some embodiments, the remaining vertical portions of the spacer layer on sidewalls of the dummy gate structures 130 can be referred to as gate spacers 115. In some embodiments, the spacer layer may be deposited using techniques such CVD, ALD, or the like.

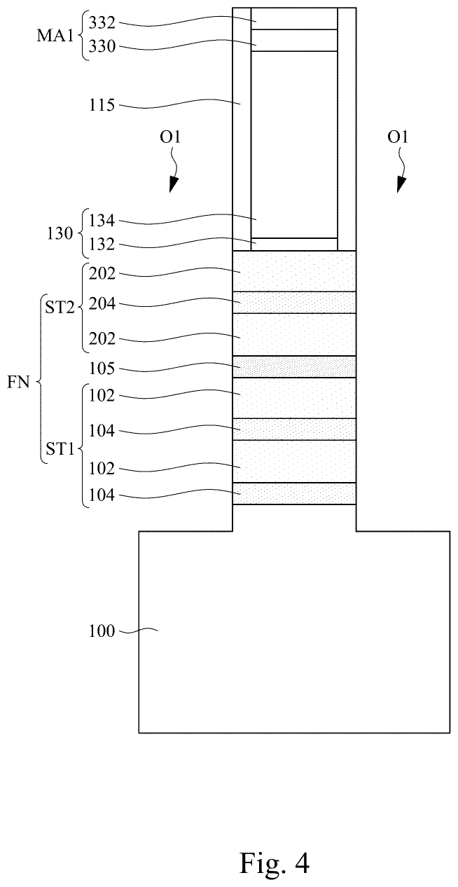

Reference is made to FIG. 4. An etching process is performed to remove portions of the fin structure FN by using the dummy gate structure 130 and the gate spacers 115 as etch mask, so as to form source/drain openings O1 in the fin structure FN. In some embodiments, the etching process may be wet etch, dry etch, or combinations thereof.

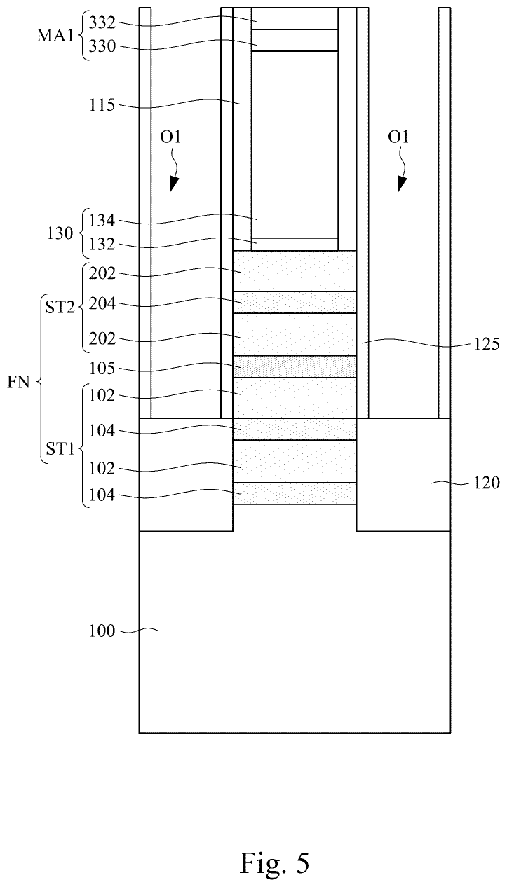

Reference is made to FIG. 5. Once the source/drain openings O1 are formed, dummy materials 120 are formed in the source/drain openings O1. In greater detail, the dummy materials 120 may be formed at lower portions of the source/drain openings O1, such that the dummy materials 120 may cover opposite sidewalls of each of the semiconductor layers 104. In some embodiments, the top surfaces of the dummy materials 120 may be lower than the semiconductor layer 105. As a result, the sidewalls of the semiconductor layers 202 may be exposed through the upper portions of the source/drain openings O1 once the dummy materials 120 are formed. In some embodiments, the dummy materials 120 may be formed by, for example, depositing one or more dummy material layers in the source/drain openings O1, and then etching back the one or more dummy material layers to lower top surfaces of the one or more dummy material layers to a desired position. In some embodiments, each of the dummy materials 120 may be made of SiOCN, or other suitable material. In other embodiments, each of the dummy materials 120 may include a liner and a filling material over the liner, in which the liner may be made of a semicoductive material, such as silicon, and the filling material may be made of a dielectric material, such as SiOCN.

Afterwards, liners 125 are formed lining sidewalls of the upper portions of the source/drain openings O1, so as to cover opposite sidewalls of the semiconductor layers 202, the semiconductor layers 204, and the semiconductor layers 105. In some embodiments, the liners 125 may also cover the sidewalls opposite sidewalls of the topmost semiconductor layer 102. The liners 125 may also cover the sidewalls of the gate spacers 115. In some embodiments, the liners 125 may be formed by, for example, depositing a liner layer blanket over the substrate, performing an anisotropic etching process to remove horizontal portions of the liner layer, such that vertical portions of the liner layer remain on sidewalls of the semiconductor layers 202, the semiconductor layers 204, the semiconductor layers 105, and the gate spacers 115. In some embodiments, the remaining vertical portions can be referred to as the liners 125. In some embodiments, the liners 125 may be made of SiN, metal oxide, or other suitable material.

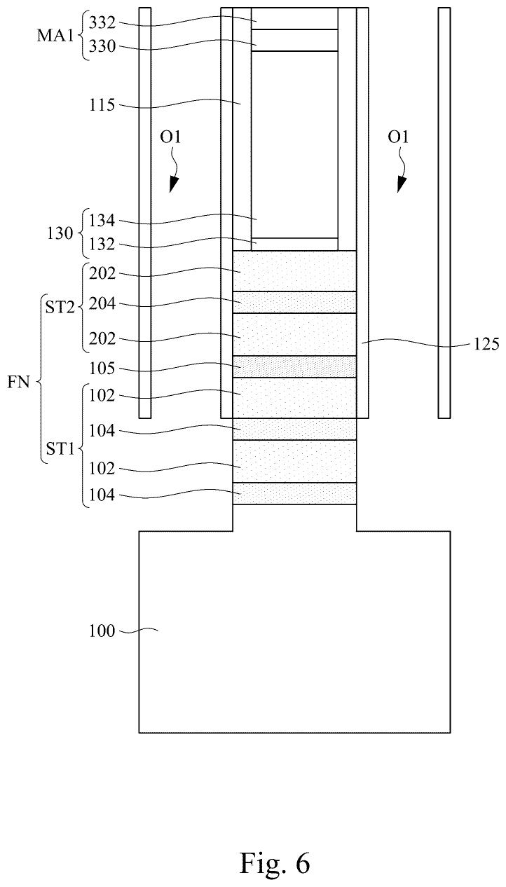

Reference is made to FIG. 6. The dummy materials 120 are removed by suitable etching process, so as to expose the sidewalls of the semiconductor layers 104 through the lower portions of the source/drain openings O1. In some embodiments, sidewalls of the semiconductor layer 102 between adjacent two of the semiconductor layers 104 may also be exposed as a result of the removal of the dummy materials 120. In some embodiments, the liners 125 may include a higher etching resistance to the etching process than the dummy materials 120, and thus the liners 125 may remain after the dummy materials 120 are removed.

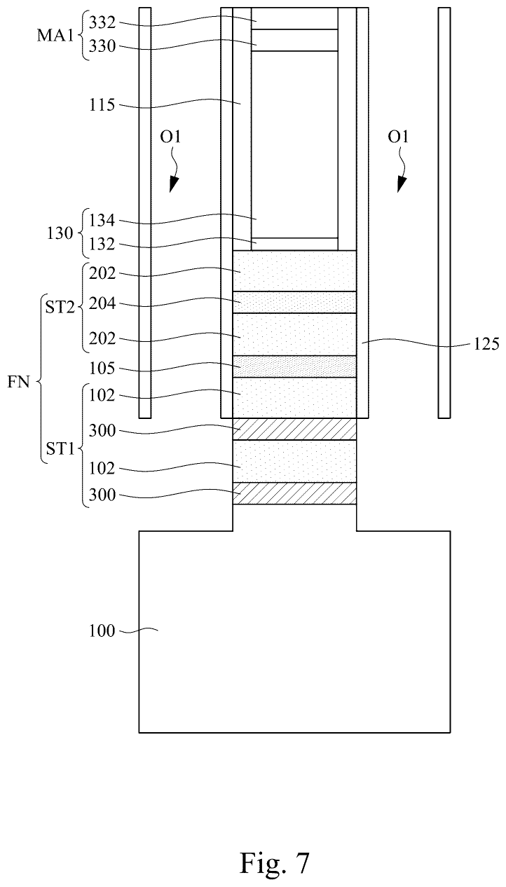

Reference is made to FIG. 7. The semiconductor layers 104 are replaced with dummy interposers 300. In some embodiments, the dummy interposers 300 may include a material that is different from the materials of the semiconductor layers 102, 104, 105, 202, and 204. In some embodiments, the dummy interposers 300 may include a material that includes a lower germanium concentration than the semiconductor layers 104 and 204. In some embodiments, the dummy interposers 300 may include a silicon-containing dielectric material, such as silicon oxide (SiO₂), silicon oxy-carbide (SiOC), silicon carbide (SiC), or other suitable materials. For example, an etching process may be performed to remove the semiconductor layers 104 to form gaps, materials of the dummy interposers 300 may be deposited in the source/drain openings O1 and filling the gaps, and then performing an etching process to remove excess materials outside of the gaps. The dummy interposers 300 may be beneficial for device boosting, and will be discussed in more detail later. In some embodiments, the dummy interposers 300 may be removed during a replacement gate (RPG) process, and thus the dummy interposers 300 can also be referred to as sacrificial layers. In some embodiments, the dummy interposers 300 can also be referred to as dielectric sacrificial layers.

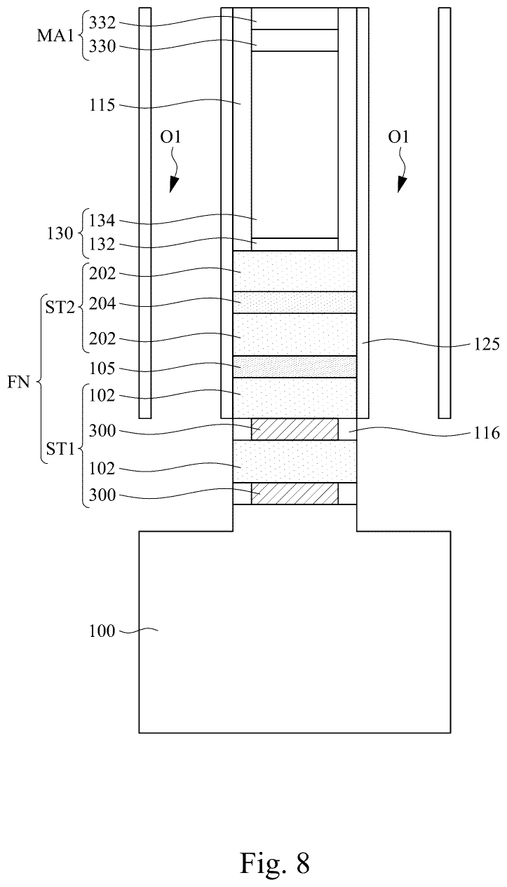

Reference is made to FIG. 8. The dummy interposers 300 are laterally etched to form sidewall recesses. In some embodiments, the sidewalls of the dummy interposers 300 may be etched using isotropic etching processes, such as wet etching or the like. Then, inner spacers 116 are formed in the sidewall recesses on opposite ends of each of the semiconductor layers 104, 105, and 204. In some embodiments, the inner spacers 116 may be formed by, for example, depositing an inner spacer layer blanket over the substrate 100 and filling the sidewall recesses, and then performing an anisotropic etching to remove portions of the inner spacer layer outside the sidewall recesses, leaving the remaining portions of the inner spacer layer in the sidewall recesses as the inner spacers 116. The inner spacers 116 may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized.

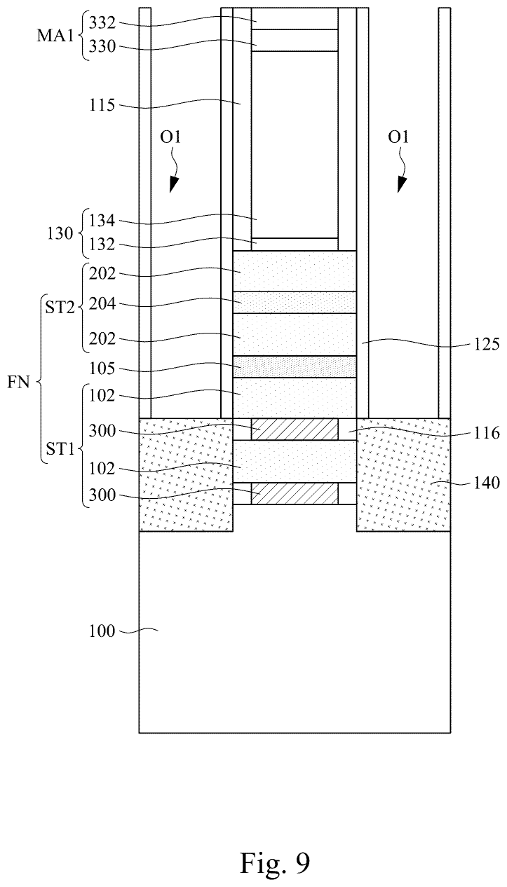

Reference is made to FIG. 9. First source/drain epitaxy structures 140 are formed on opposite ends of the exposed semiconductor layer 102. In some embodiments, the first source/drain epitaxy structures 140 may be formed by a selective epitaxial growth (SEG) process. The SEG process may selectively grow a semiconductor material on exposed semiconductor surfaces, such as the exposed surfaces of the semiconductor layer 102. On the other hand, the SEG process would not grow a semiconductor material from surfaces of the semiconductor layers 202, because the surfaces of the semiconductor layers 202 are covered by the liners 125. In other embodiments, the SEG process may not grow a semiconductor material from surfaces of the topmost semiconductor layer 102, because the surfaces of the topmost semiconductor layer 102 are also covered by the liners 125. In some embodiments, the first source/drain epitaxy structures 140 may be doped with p-type dopants, such as boron (B), gallium (Ga), indium (In), aluminium (Al), or the like.

In some embodiments, the first source/drain epitaxy structures 140 may include a material that is able to induce a strain to the semiconductor layers 102. For example, when the first source/drain epitaxy structures 140 is made of silicon germanium (SiGe) and the semiconductor layers 102 are made of silicon (Si), the first source/drain epitaxy structures 140 may induce tensile stress to the semiconductor layers 102, which is beneficial for increasing carrier mobility of a P-type device (e.g., the first transistor TR1). However, because the semiconductor layers 104 may include a same material as the first source/drain epitaxy structures 140, such as silicon germanium (SiGe), the tensile stress induced from the semiconductor layers 104 to the semiconductor layers 102 may degrade the tensile stress induced from the first source/drain epitaxy structures 140 to the semiconductor layers 102, which will even out the advantage provided by the first source/drain epitaxy structures 140. Accordingly, by replacing the semiconductor layers 104 with the dummy interposers 300 having less germanium impurities, the dummy interposers 300 may induce less tensile stress on the semiconductor layers 102, and thus the performance of the bottom P-type device (e.g., the first transistor TR1) can be improved.

On the other hand, during replacing the semiconductor layers 104 with the dummy interposers 300, the semiconductor layers 204 are protected by the liners 125. That is, the semiconductor layers 204 may not be replaced with the dummy interposers 300. Such configuration may be beneficial for the top N-type device (e.g., the second transistor TR2). In some embodiments, if the semiconductor layers 204 are replaced with the dummy interposers 300, the dummy interposers 300 may induce less tensile stress on the semiconductor layers 202, while the less tensile stress may degrade the device performance of an N-type device. Accordingly, by replacing only the semiconductor layers 104 with dummy interposers 300, there is no impact on the top N-type device (e.g., the second transistor TR2). With such method, the device performance of the CFET can be improved.

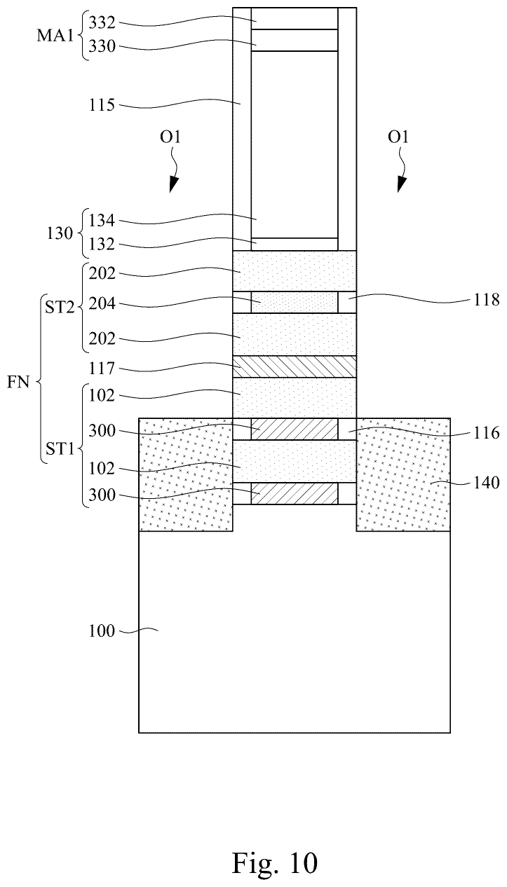

Reference is made to FIG. 10. After the first source/drain epitaxy structures 140 are formed, the liners 125 are removed through suitable etching process. After the liners 125 are removed, the sidewalls of the topmost semiconductor layer 102 and sidewalls of the semiconductor layers 105, 202, and 204 are exposed.

Then, inner spacers 118 are formed on opposite ends of the semiconductor layers 204, and the semiconductor layer 105 is replaced with an isolation material 117. The inner spacers 118 and the isolation material 117 may be made of a same material as the inner spacers 116 as discussed above. However, the inner spacers 118 and the isolation material 117 may be made of a same material, which is different from the material of the inner spacers 116.

The inner spacers 118 and the isolation material 117 may be formed by, for example, performing an etching process on the semiconductor layers 105 and 204, so as to form sidewall recesses on opposite sides of each of the semiconductor layers 204 and to form a gap between the topmost semiconductor layer 102 and the bottom most semiconductor layer 202. A spacer layer is deposited blanket over the substrate 100 and filling the sidewall recesses and the gap, and then performing an anisotropic etching to remove portions of the spacer layer outside the sidewall recesses and the gap, leaving the remaining portions of the spacer layer in the sidewall recesses as the inner spacers 118 and the remaining portion of the spacer layer in the gap as the isolation material 117. The inner spacers 118 and the isolation material 117 may be deposited by a conformal deposition process, such as CVD, ALD, or the like.

During forming the inner spacers 116, a first etching process may be performed to trim the dummy interposers 300, and then the inner spacers 116 are formed on opposite ends of the trimmed dummy interposers 300. On the other hand, during forming the inner spacers 118, a second etching process may be performed to trim the semiconductor layer 204, and then the inner spacers 118 are formed on opposite ends of the trimmed semiconductor layer 204. Because the semiconductor layer 204 and the dummy interposers 300 are made of different materials, the first etching process and the second etching process may be performed using different etchants.

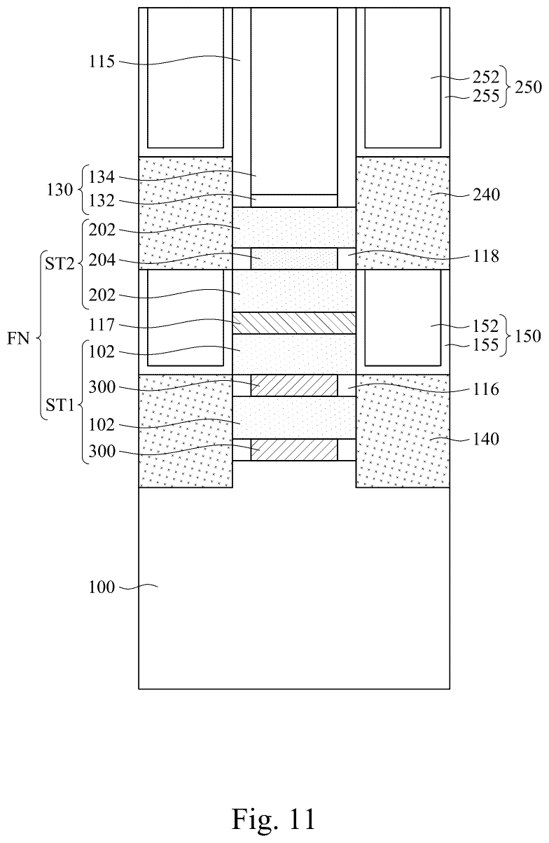

Reference is made to FIG. 11. A contact etch stop layer (CESL) 155 is formed covering the first source/drain epitaxy structures 140. Afterwards, an interlayer dielectric (ILD) layer 152 is formed over the CESL 155. Then, an etching back process is performed to lower top surfaces of the CESL 155 and the ILD layer 152 to a position, such that at least the topmost one of the semiconductor layers 202 are exposed through the source/drain openings O1. In some embodiments, the CESL 155 and the ILD layer 152 can be collectively referred to as an isolation structure 150. In some embodiments, the bottommost one of the semiconductor layers 202 may be covered by the isolation structure 150.

In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 155 and the ILD layer 152 can be formed using, for example, CVD, ALD or other suitable techniques.

Second source/drain epitaxy structures 240 are formed on opposite ends of the exposed semiconductor layer 202. In some embodiments, the second source/drain epitaxy structures 240 may be formed by a selective epitaxial growth (SEG) process. The SEG process may selectively grow a semiconductor material on exposed semiconductor surfaces, such as the exposed surfaces of the exposed semiconductor layer 202. In some embodiments, the second source/drain epitaxy structures 240 may be doped with n-type dopants, such as phosphorus (P), arsenic (As), or antimony (Sb), or the like.

In some embodiments, during forming the first source/drain epitaxy structures 140 and the second source/drain epitaxy structures 240, a relative high temperature may be used to form a crystalline structure of the first source/drain epitaxy structures 140 and the second source/drain epitaxy structures 240. The relative high temperature may also cause element diffusion from the dummy interposers 300 to the adjacent structures and cause element diffusion from the semiconductor layer 204 to the adjacent structures.

For example, when the dummy interposers 300 include silicon oxide (SiO₂), silicon oxy-carbide (SiOC), or silicon carbide (SiC), oxygen (O) or carbon (C) element may be diffused into the inner spacers 116 or the semiconductor layers 102 during forming the first source/drain epitaxy structures 140. As a result, oxygen (O) or carbon (C) may be detectable in the inner spacers 116 or the semiconductor layers 102, and the inner spacers 116 and the semiconductor layers 102 may include higher oxygen (O) concentration or carbon (C) concentration than the inner spacers 118 and the semiconductor layers 202.

On the other hand, when the semiconductor layer 204 include silicon germanium (SiGe), germanium (Ge) element may be diffused into the inner spacers 118 or the semiconductor layers 202 during forming the second source/drain epitaxy structures 240. As a result, germanium (Ge) may be detectable in the inner spacers 118 or the semiconductor layers 202, and the inner spacers 118 and the semiconductor layers 202 may include higher germanium (Ge) concentration than the inner spacers 116 and the semiconductor layers 102. Accordingly, the inner spacers 116 and 118 may be different in composition, and the semiconductor layers 102 and 202 may be different in composition.

A contact etch stop layer (CESL) 255 is formed covering the second source/drain epitaxy structures 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structure 130 is exposed. In some embodiments, the patterned masks MA1 are removed during the planarization process. In some embodiments, the CESL 255 and the ILD layer 252 can be collectively referred to as an isolation structure 250. The materials of the CESL 255 and the ILD layer 252 may be similar to the materials of the CESL 155 and the ILD layer 152, respectively, and thus relevant details will not be repeated for brevity.

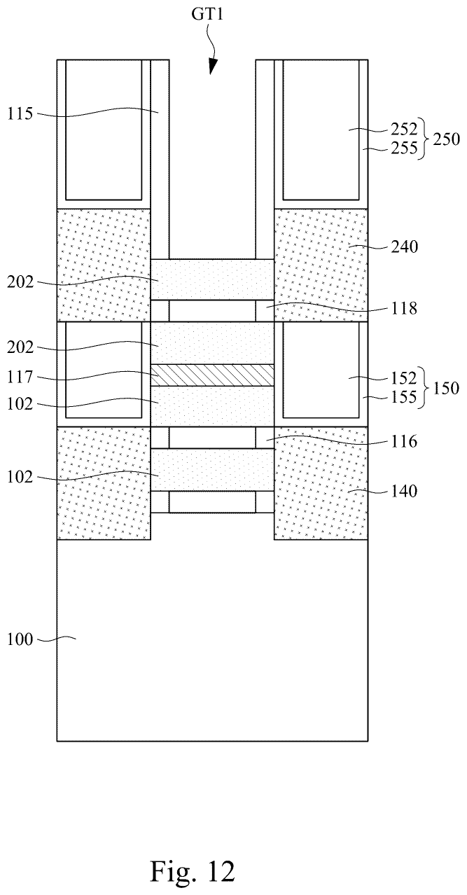

Reference is made to FIG. 12. The dummy gate structure 130 is removed to form gate trench GT1 between the gate spacers 115. Then, a first etching process is performed to remove the semiconductor layers 204, such that at least the topmost one of the semiconductor layers 202 is suspended over the substrate 100. A second etching process is performed to remove the dummy interposers 300, such that at least the bottommost one of the semiconductor layers 102 is suspended over the substrate 100. In some embodiments, the first etching process is performed prior to or after the second etching process. That is, the semiconductor layers 204 and the dummy interposers 300 are removed at different time points. In some embodiments, because the dummy interposers 300 and the semiconductor layers 204 are made of different materials. The etchant of the first etching process may be different from the etchant of the second etching process.

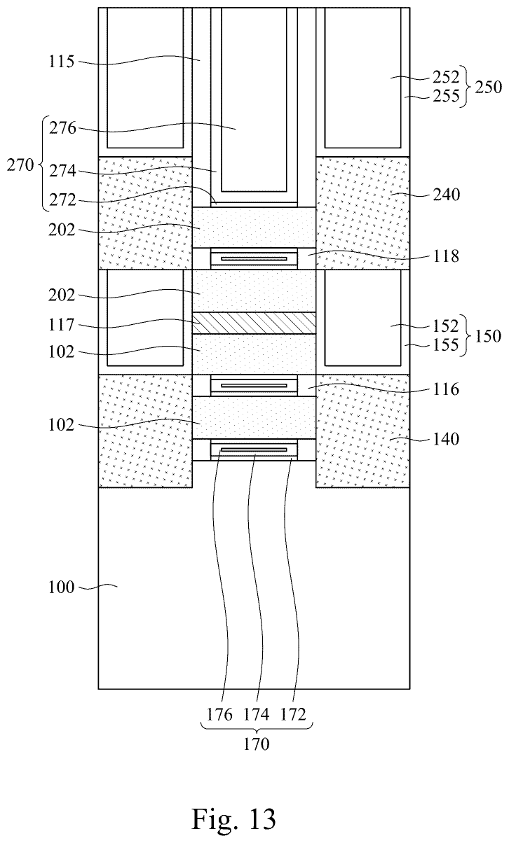

Reference is made to FIG. 13. Interfacial layers 172 and 272 are formed on exposed surfaces of the semiconductor layers 102 and 202, respectively. Then, gate dielectric layers 174 and 274 are formed over the interfacial layers 172 and 272, respectively. In some embodiments, the interfacial layers 172 and 272 may be formed using a same deposition process, and the gate dielectric layers 174 and 274 may be formed using a same deposition process.

After the interfacial layers 172 and 272 and the gate dielectric layers 174 and 274 are formed, gate electrodes 176 and 276 are formed in the gate trench GT1 and over the gate dielectric layers 174 and 274, respectively. In some embodiments, the gate electrodes 176 and 276 may include a same material or different materials. In the embodiments where the gate electrodes 176 and 276 are made of different materials, the gate electrode 176 is formed in the gate trench GT1, the gate electrode 176 is then etched back, such that the remaining gate electrode 176 is at the lower portion of the gate trench GT1. Afterwards, the gate electrode 276 is then formed in the upper portion of the gate trench GT1 and over the gate dielectric layers 274.

Accordingly, first metal gate structure 170 and second metal gate structure 270 are formed. In greater detail, the first metal gate structure 170 is formed in bottom portion of the gate trench GT1, such that the first metal gate structure 170 may wrap around the respective semiconductor layer 102. The second metal gate structure 270 is formed in upper portion of the gate trench GT1 and above the first metal gate structure 170, such that the second metal gate structure 270 may wrap around the respective semiconductor layer 202. In some embodiments, the first metal gate structure 170 may include the interfacial layer 172, the gate dielectric layer 174 over the interfacial layer 172, and the gate electrode 176 over the gate dielectric layer 174. The second metal gate structure 270 may include the interfacial layer 272, the gate dielectric layer 274 over the interfacial layer 272, and the gate electrode 276 over the gate dielectric layer 274.

In some embodiments, the interfacial layers 172 and 272 may be made of oxide, such as aluminum oxide (Al₂O₃), silicon oxide (SiO₂), or the like. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrodes 176 and 276 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

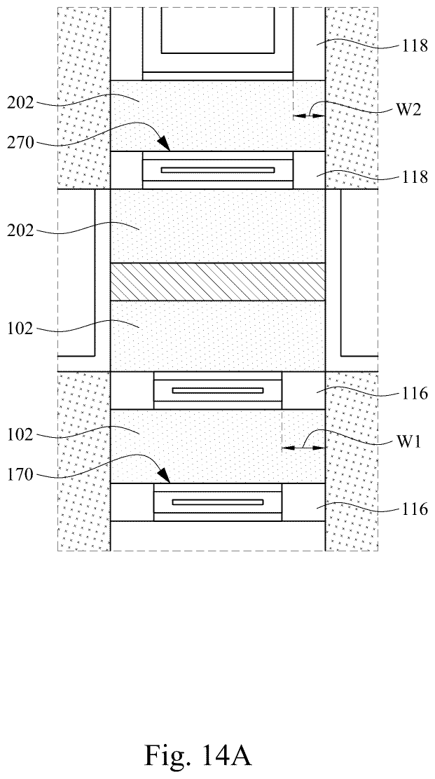

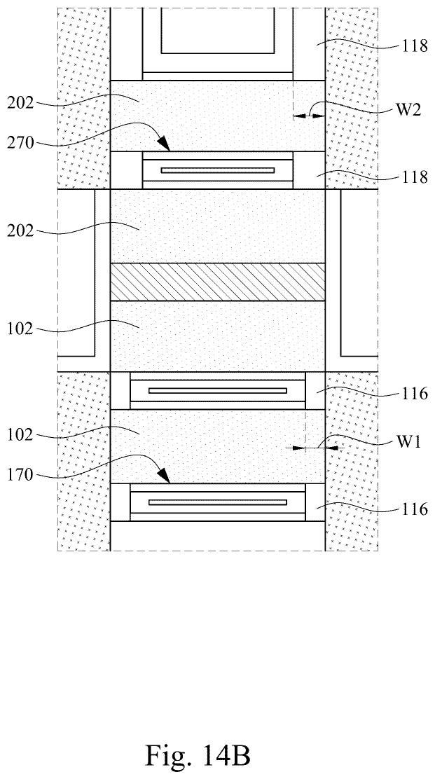

FIGS. 14A and 14B are cross-sectional views of a semiconductor device in accordance with some embodiments of the present disclosure. It is noted that some elements of FIGS. 14A and 14B have been discussed above with respect to FIGS. 1 to 13, such elements are labeled the same and relevant details will not be repeated for brevity.

In FIG. 14A, because the inner spacers 116 and 118 are formed at different time points, the dimension (e.g., width) of the inner spacers 116 and 118 may be different. In the embodiments of FIG. 14A, the inner spacers 116 each may include a width W1, and the inner spacers 118 each may include a width W2, in which the width W1 is greater than the width W2. In such embodiments, a portion of the first metal gate structure 170 between a pair of the inner spacers 116 may be narrower than a portion of the second metal gate structure 270 between a pair of the inner spacers 118.

In FIG. 14B, the inner spacers 116 each may include a width W1, and the inner spacers 118 each may include a width W2, in which the width W1 is less than the width W2. In such embodiments, a portion of the first metal gate structure 170 between a pair of the inner spacers 116 may be wider than a portion of the second metal gate structure 270 between a pair of the inner spacers 118.

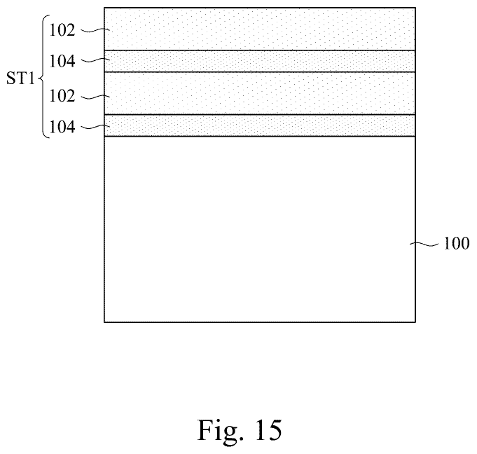

FIGS. 15 to 27 illustrate a method in various stages of forming a semiconductor device in accordance with some embodiments of the present disclosure. It is noted that some elements of FIGS. 15 to 27 have been discussed above with respect to FIGS. 1 to 13, such elements are labeled the same and relevant details (e.g. formation method and material) will not be repeated for brevity.

Reference is made to FIG. 15. Shown there is a substrate 100. Then, a first stack ST1 of alternating semiconductor layers 102 and 104 is formed over the substrate 100.

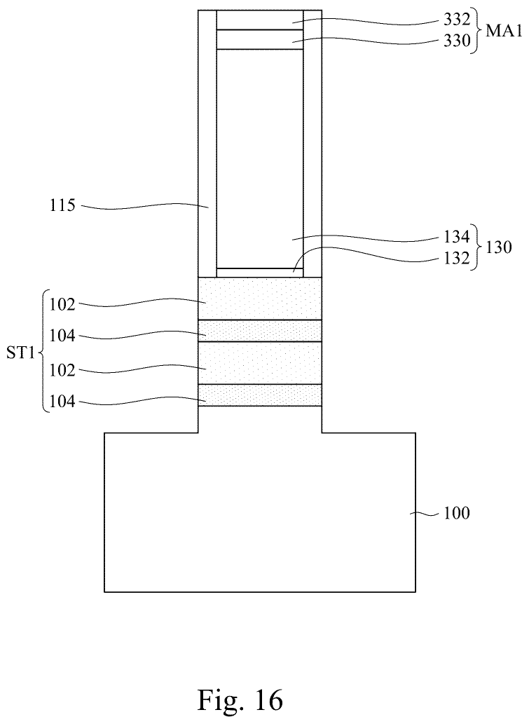

Reference is made to FIG. 16. A dummy gate structure 130 is formed over the substrate 100 and crossing the first stack ST1 of alternating semiconductor layers 102 and 104. The dummy gate structure 130 may include a dummy gate dielectric 132 and a dummy gate electrode 134 over the dummy gate dielectric 132. In some embodiments, a patterned mask MA1 is disposed over the dummy gate structure 130. Spacers 115 are formed on opposite sidewalls of each of the dummy gate structure 130. An etching process is performed to remove portions of the stack ST1 and the substrate 100 by using the dummy gate structure 130 and the spacers 115 as etch mask, so as to form source/drain openings.

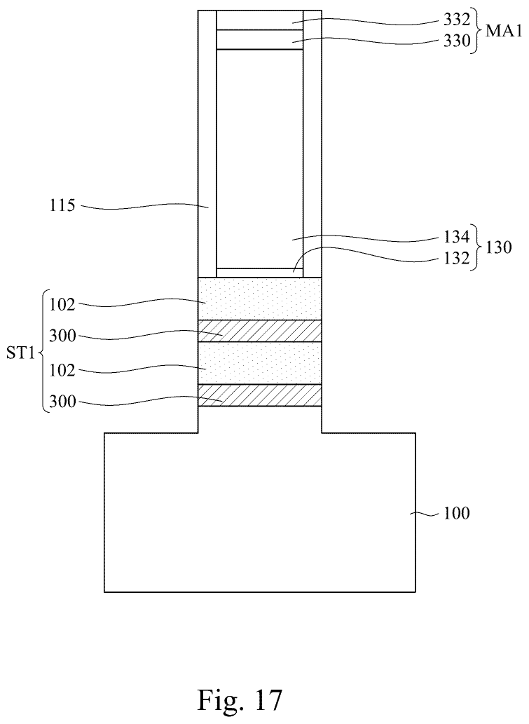

Reference is made to FIG. 17. The semiconductor layers 104 are replaced with dummy interposers 300. For example, an etching process may be performed to remove the semiconductor layers 104 to form gaps, materials of the dummy interposers 300 may be deposited in the source/drain openings and filling the gaps, and then performing an etching process to remove excess materials outside of the gaps.

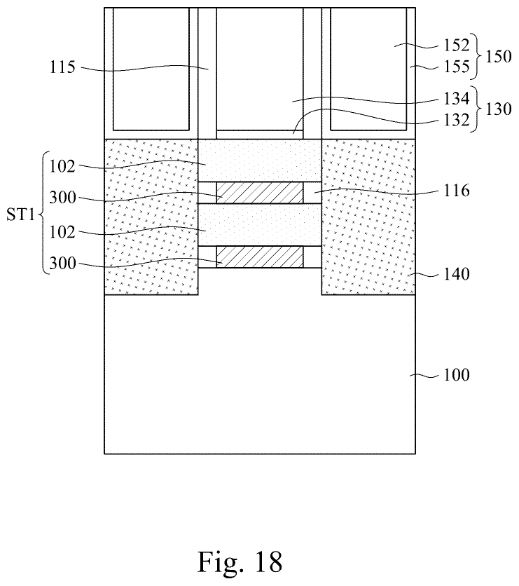

Reference is made to FIG. 18. The dummy interposers 300 are laterally etched to form sidewall recesses. In some embodiments, the sidewalls of the dummy interposers 300 may be etched using isotropic etching processes, such as wet etching or the like. Then, inner spacers 116 are formed in the sidewall recesses. First source/drain epitaxy structures 140 are formed in the source/drain openings and on opposite ends of the exposed semiconductor layer 102. A contact etch stop layer (CESL) 155 is formed covering the first source/drain epitaxy structures 140. Afterwards, an interlayer dielectric (ILD) layer 152 is formed over the CESL 155. In some embodiments, the CESL 155 and the ILD layer 152 can be collectively referred to as an isolation structure 150.

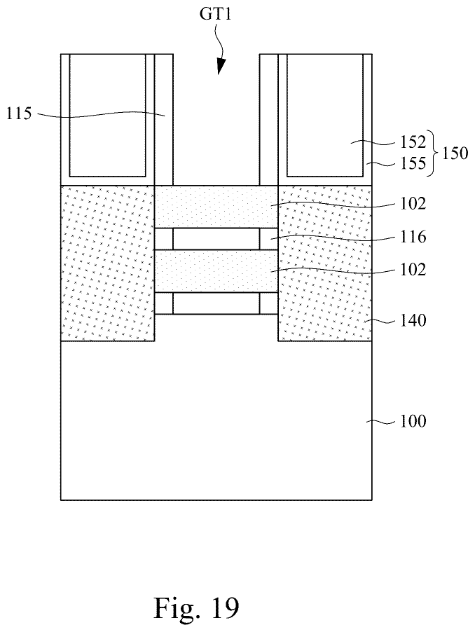

Reference is made to FIG. 19. The dummy gate structure 130 is removed to form gate trench GT1 between the gate spacers 115. Then, an etching process is performed to remove the dummy interposers 300, such that the semiconductor layers 102 are suspended over the substrate 100.

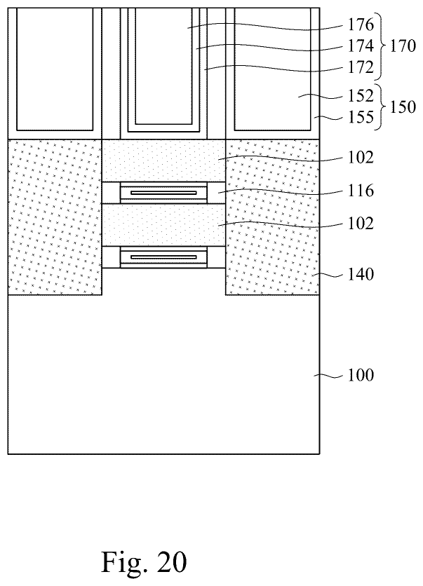

Reference is made to FIG. 20. A first metal gate structure 170 is formed in the gate trench GT1 and wrapping around the semiconductor layers 102, respectively. In some embodiments, the first metal gate structure 170 may include an interfacial layer 172, a gate dielectric layer 174 over the interfacial layer 172, and a gate electrode 176 over the gate dielectric layer 174.

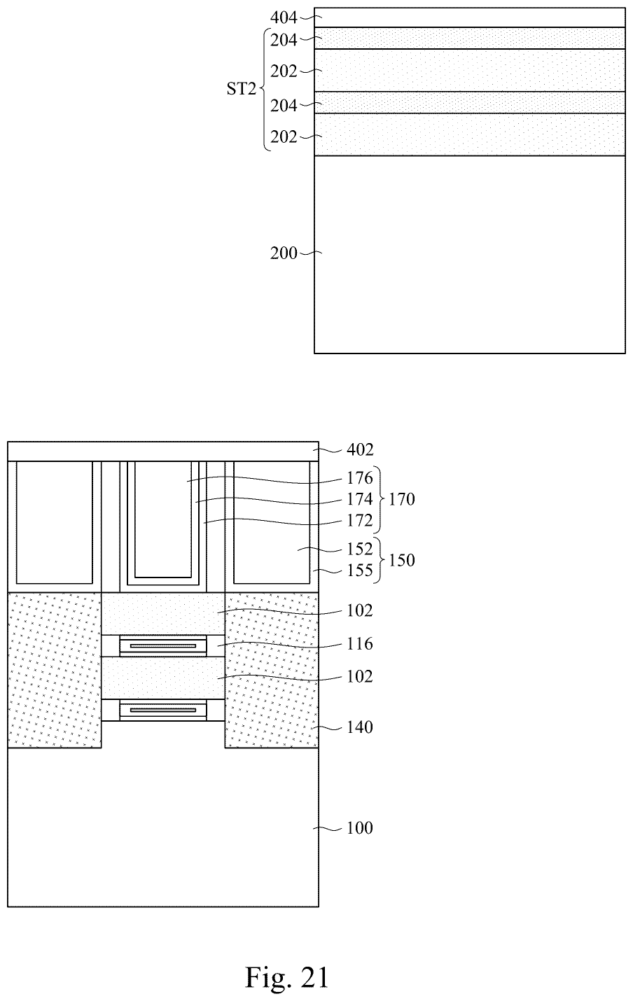

Reference is made to FIG. 21. A bonding layer 402 is formed over the structure shown in FIG. 20. In greater detail, the bonding layer 402 may be in contact with the first metal gate structure 170, the spacers 115, and the isolation structures 150. In some embodiments, the bonding layer 402 may be deposited over the structure shown in FIG. 20 using suitable deposition process, such as CVD, PVD, ALD, or the like.

On the other hand, a substrate 200 is provided. The substrate 200 may include a similar material as the substrate 100. A second stack ST2 of alternating semiconductor layers 202 and 204 are formed over the substrate 200.

A bonding layer 404 is formed over the second stack ST2. In some embodiments, the bonding layer 304 is in contact with a semiconductor layer 204. The bonding layers 402 and 404 may include dielectric material such as silicon oxide (SiOₓ), silicon dioxide (SiO₂), or other suitable materials. In some embodiments, the bonding layers 402 and 404 may include a same bonding material. In other embodiments, the bonding layers 402 and 404 may include different bonding materials.

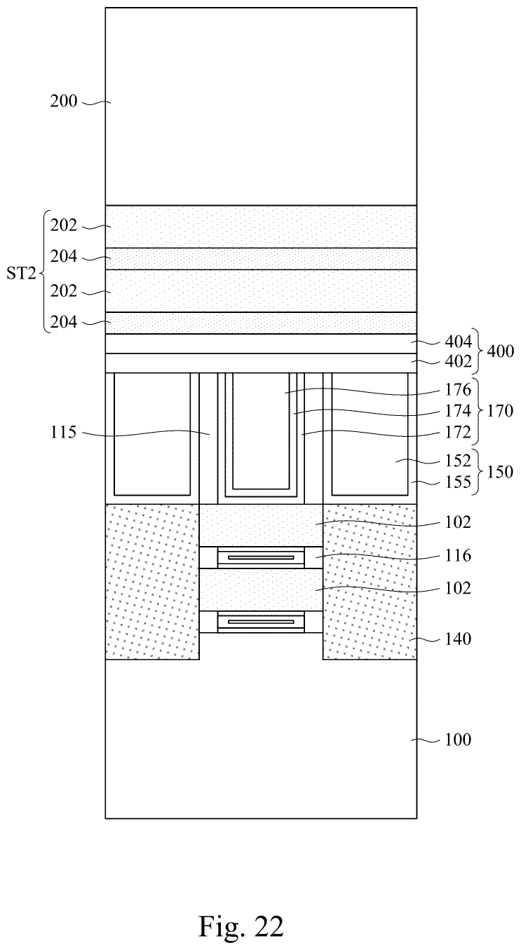

Reference is made to FIG. 22. The substrate 100 is bonded to the substrate 200. For example, the substrate 200 is flipped over by, for example 180 degrees, such that the bonding layer 404 on the substrate 200 faces the bonding layer 402 on the substrate 100.

Then, the bonding layers 402 and 404 are bonded with each other using a suitable technique. In some embodiments, the bonding process may further include applying surface treatments to the surfaces of the bonding layers 402 and 404, respectively. The surface treatment may include a plasma treatment. The plasma treatment may be performed in a vacuum environment. After the plasma treatment, the surface treatment may further include a cleaning process (e.g., a rinse with deionized water, or the like) that may be applied to the bonding layers 402 and 404. The bonding layers 402 and 404 are pressed against each other to initiate a pre-bonding of the substrates 100 and 200. An annealing process may be performed to increase bonding force between the bonding layers 402 and 404, such that even if the bonding layers 402 and 404 are no longer subjected to the pressing force, they will not delaminate or peel from each other. In some embodiments, the bonding layers 402 and 404 can be collectively referred to as a bonding structure 400.

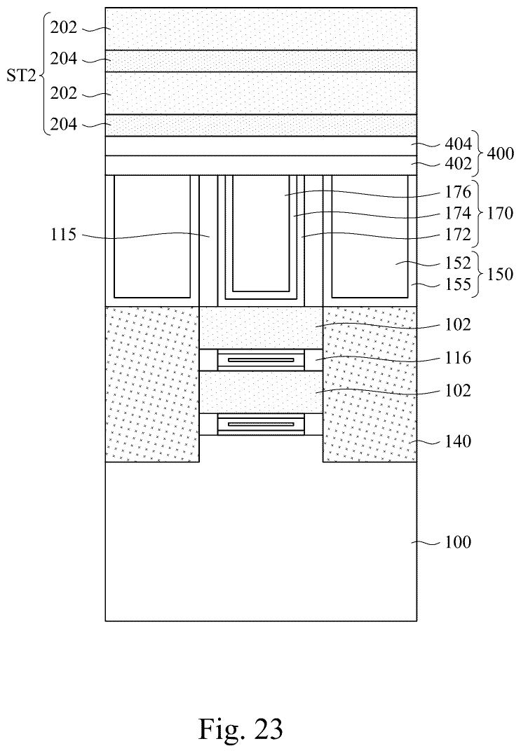

Reference is made to FIG. 23. A grinding process is performed on the backside of the substrate 200 (see FIG. 22), so as to remove the substrate 200 until the topmost semiconductor layer 202 is exposed.

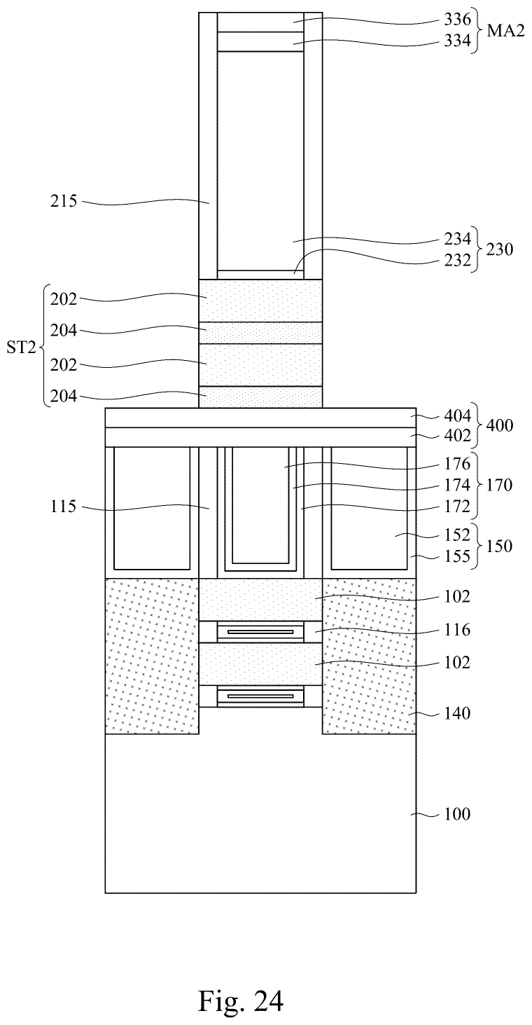

Reference is made to FIG. 24. A dummy gate structure 230 is formed over the substrate 200 and crossing the second stack ST2 of alternating semiconductor layers 202 and 204. The dummy gate structure 230 may include a dummy gate dielectric 232 and a dummy gate electrode 234 over the dummy gate dielectric 232. In some embodiments, a patterned mask MA2 is disposed over the dummy gate structure 230. In some embodiments, the patterned mask MA2 includes a first hard mask 334 and a second hard mask 336 over the first hard mask 334. Spacers 215 are formed on opposite sidewalls of each of the dummy gate structure 230. An etching process is performed to remove portions of the stack ST2 and the substrate 200 by using the dummy gate structure 230 and the spacers 215 as etch mask, so as to form source/drain openings. In some embodiments, the dummy gate dielectric 232 and the dummy gate electrode 234 may be similar to the dummy gate dielectric 132 and the dummy gate electrode 134 as discussed above. The first hard mask 334 and the second hard mask 336 may be similar to the first hard mask 330 and the second hard mask 332 as discussed above.

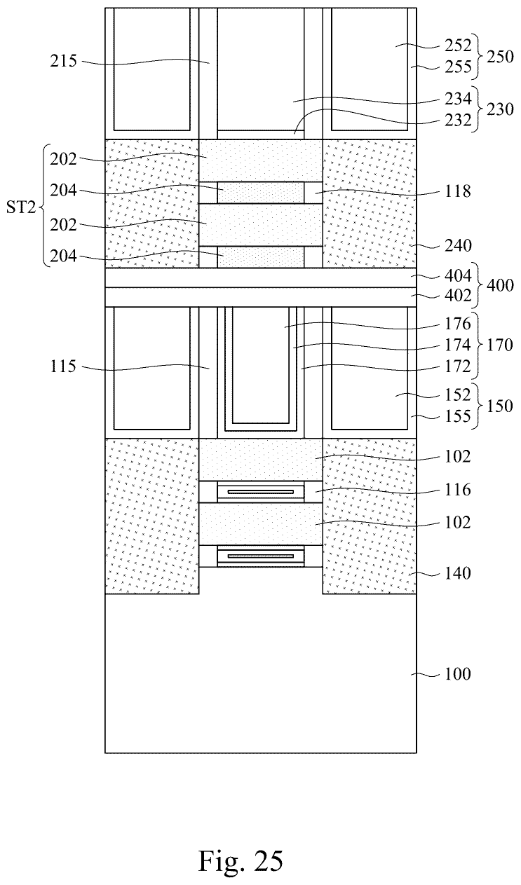

Reference is made to FIG. 25. The semiconductor layers 204 are laterally etched to form sidewall recesses. In some embodiments, the sidewalls of the semiconductor layers 204 may be etched using isotropic etching processes, such as wet etching or the like. In some embodiments, etchant for laterally etching the semiconductor layers 204 may be different from the etchant for laterally etching the dummy interposers 300. Then, inner spacers 118 are formed in the sidewall recesses. Second source/drain epitaxy structures 240 are formed in the source/drain openings and on opposite ends of the exposed semiconductor layer 202. A contact etch stop layer (CESL) 255 is formed covering the second source/drain epitaxy structures 240. Afterwards, an interlayer dielectric (ILD) layer 252 is formed over the CESL 255. In some embodiments, the CESL 255 and the ILD layer 252 can be collectively referred to as an isolation structure 250.

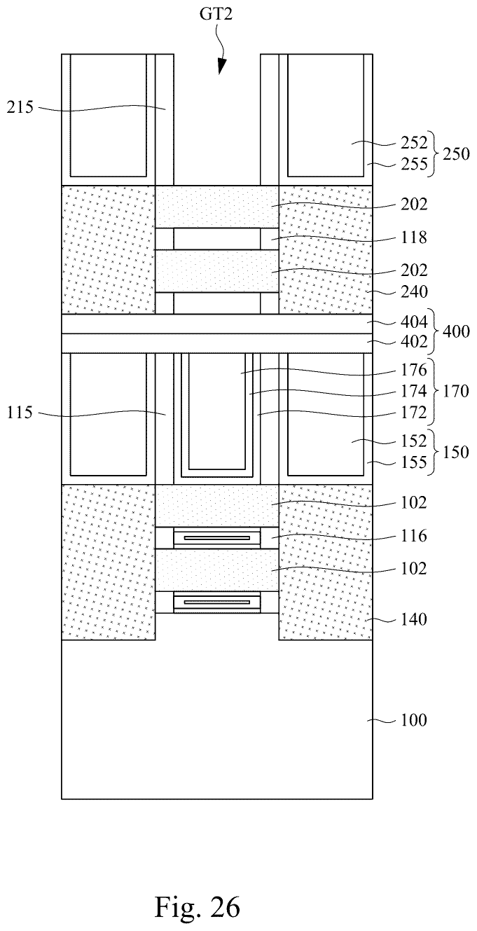

Reference is made to FIG. 26. The dummy gate structure 230 is removed to form gate trench GT2 between the gate spacers 215. Then, an etching process is performed to remove the semiconductor layers 204, such that the semiconductor layers 202 are suspended over the substrate 100. In some embodiments, etchant for removing the semiconductor layers 204 may be different from the etchant for removing the dummy interposers 300.

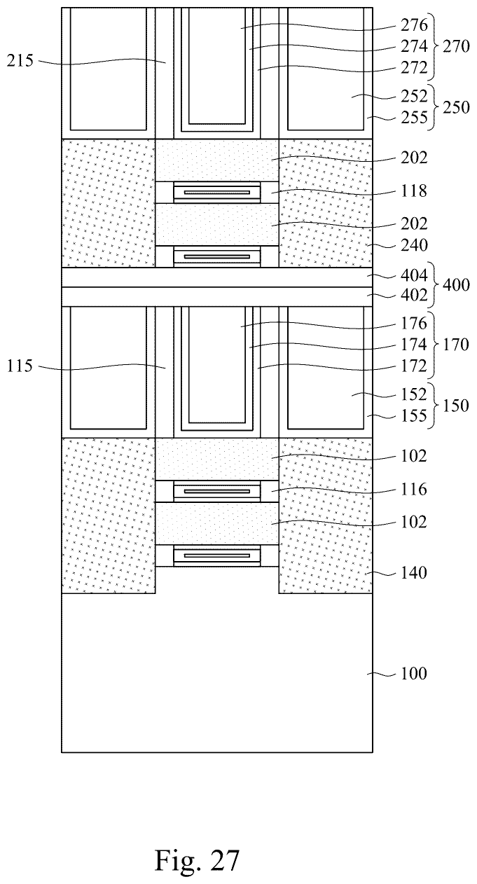

Reference is made to FIG. 27. A second metal gate structure 270 is formed in the gate trench GT2 and wrapping around the semiconductor layers 202, respectively. In some embodiments, the second metal gate structure 270 may include an interfacial layer 272, a gate dielectric layer 274 over the interfacial layer 272, and a gate electrode 276 over the gate dielectric layer 274. In some embodiments, the inner spacers 116 and 118 may include a similar relationship as discussed in FIGS. 14A and 14B, and the first metal gate structure 170 and the second metal gate structure 270 may include a similar relationship as discussed in FIGS. 14A and 14B.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method for forming a CFET. By replacing the bottom sacrificial layers with dummy interposers having less germanium impurities, the dummy interposers may induce less tensile stress on the bottom semiconductor channel layers, and thus the performance of the bottom P-type device can be improved. Moreover, by replacing only the bottom sacrificial layers with the dummy interposers, there is no impact on the top semiconductor channel layers of the top N-type device. With such method, the device performance of the CFET can be improved.

In some embodiments of the present disclosure, a method includes forming a first stack of alternating first semiconductor layers and first sacrificial layers over a substrate and a second stack of alternating second semiconductor layers and second sacrificial layers over the first stack; replacing the first sacrificial layers with dummy interposers, respectively; forming first source/drain epitaxy structures on opposite sides of the first semiconductor layers; forming second source/drain epitaxy structures on opposite sides of the second semiconductor layers; removing the second sacrificial layers and the dummy interposers; and forming a first gate structure wrapping around at least one of the first semiconductor layers and a second gate structure wrapping around at least one of the second semiconductor layers.

In some embodiments, a material of the dummy interposers has a lower germanium concentration that the first sacrificial layers.

In some embodiments, the dummy interposers include silicon oxide (SiO₂), silicon oxy-carbide (SiOC), or silicon carbide (SiC).

In some embodiments, the method further includes forming liners covering the second sacrificial layers prior to replacing the first sacrificial layers with the dummy interposers; and removing the liners after replacing the first sacrificial layers with the dummy interposers.

In some embodiments, the method further includes forming first inner spaces on opposite ends of the dummy interposers.

In some embodiments, the method further includes forming second inner spaces on opposite ends of the second sacrificial layers after forming the first inner spaces.

In some embodiments, the first sacrificial layers and the dummy interposers are removed at different time points.

In some embodiments, the first and second sacrificial layers are made of a first material and the dummy interposers are made of a second material different from the first material.

In some embodiments of the present disclosure, a method includes forming a first stack of alternating bottom semiconductor layers and dielectric sacrificial layers over a substrate and a second stack of alternating top semiconductor layers and top semiconductor sacrificial layers over the first stack; forming bottom source/drain epitaxy structures on opposite sides of the bottom semiconductor layers; forming top source/drain epitaxy structures on opposite sides of the top semiconductor layers; removing the dielectric sacrificial layers and the top semiconductor sacrificial layers; and forming a bottom gate structure wrapping around at least one of the bottom semiconductor layers and a top gate structure wrapping around at least one of the top semiconductor layers.

In some embodiments, forming the first stack of the bottom semiconductor layers and the dielectric sacrificial layers comprises forming the bottom semiconductor layers and bottom semiconductor sacrificial layers alternately stacked over the substrate; and replacing the bottom semiconductor sacrificial layers with the dielectric sacrificial layers.

In some embodiments, the method further includes forming liners covering the top semiconductor sacrificial layers prior to replacing the bottom semiconductor sacrificial layers with the dielectric sacrificial layers; and removing the liners after replacing the bottom semiconductor sacrificial layers with the dielectric sacrificial layers.

In some embodiments, the method further includes forming first inner spaces on opposite ends of the dielectric sacrificial layers; and after forming the first inner spaces, forming second inner spaces on opposite ends of the top semiconductor sacrificial layers.

In some embodiments, the dielectric sacrificial layers are made of a silicon-containing dielectric material.

In some embodiments, removing the dielectric sacrificial layers and the top semiconductor sacrificial layers comprises performing a first etching process to remove the dielectric sacrificial layers; and performing a second etching process to remove the top semiconductor sacrificial layers, wherein the first etching process and the second etching process are performed at different time points.

In some embodiments, an etchant of the first etching process is different from an etchant of the second etching process.

In some embodiments of the present disclosure, a semiconductor device includes a first transistor and a second transistor stacked above the first transistor. The first transistor includes a first semiconductor channel layer, first source/drain structures on opposite ends of the first semiconductor channel layer, and a first gate structure wrapping around the first semiconductor channel layer. The second transistor includes a second semiconductor channel layer, second source/drain structures on opposite ends of the second semiconductor channel layer, and a second gate structure wrapping around the second semiconductor channel layer. First inner spacers on opposite sides of a portion of the first gate structure. Second inner spacers on opposite sides of a portion of the second gate structure, in which the first inner spacers and the second inner spacers are different in composition.

In some embodiments, the first inner spacers include higher oxygen concentration or carbon concentration than the second inner spacers.

In some embodiments, the second inner spacers include higher germanium concentration than the first inner spacers.

In some embodiments, the second semiconductor channel layer includes higher germanium concentration than the first semiconductor channel layer.

In some embodiments, the first inner spacers and the second inner spacers have different widths.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first stack of alternating first semiconductor layers and first sacrificial layers over a substrate and a second stack of alternating second semiconductor layers and second sacrificial layers over the first stack;
replacing the first sacrificial layers with dummy interposers, respectively;
forming first source/drain epitaxy structures on opposite sides of the first semiconductor layers;
forming second source/drain epitaxy structures on opposite sides of the second semiconductor layers;
removing the second sacrificial layers and the dummy interposers; and
forming a first gate structure wrapping around at least one of the first semiconductor layers and a second gate structure wrapping around at least one of the second semiconductor layers.

2. The method of claim 1, wherein a material of the dummy interposers has a lower germanium concentration that the first sacrificial layers.

3. The method of claim 1, wherein the dummy interposers include silicon oxide (SiO₂), silicon oxy-carbide (SiOC), or silicon carbide (SiC).

4. The method of claim 1, further comprising:
forming liners covering the second sacrificial layers prior to replacing the first sacrificial layers with the dummy interposers; and
removing the liners after replacing the first sacrificial layers with the dummy interposers.

5. The method of claim 1, further comprising forming first inner spaces on opposite ends of the dummy interposers.

6. The method of claim 5, further comprising forming second inner spaces on opposite ends of the second sacrificial layers after forming the first inner spaces.

7. The method of claim 1, wherein the first sacrificial layers and the dummy interposers are removed at different time points.

8. The method of claim 1, wherein the first and second sacrificial layers are made of a first material and the dummy interposers are made of a second material different from the first material.

9. A method, comprising:
forming a first stack of alternating bottom semiconductor layers and dielectric sacrificial layers over a substrate and a second stack of alternating top semiconductor layers and top semiconductor sacrificial layers over the first stack;
forming bottom source/drain epitaxy structures on opposite sides of the bottom semiconductor layers;
forming top source/drain epitaxy structures on opposite sides of the top semiconductor layers;
removing the dielectric sacrificial layers and the top semiconductor sacrificial layers; and
forming a bottom gate structure wrapping around at least one of the bottom semiconductor layers and a top gate structure wrapping around at least one of the top semiconductor layers.

10. The method of claim 9, wherein forming the first stack of the bottom semiconductor layers and the dielectric sacrificial layers comprises:
forming the bottom semiconductor layers and bottom semiconductor sacrificial layers alternately stacked over the substrate; and
replacing the bottom semiconductor sacrificial layers with the dielectric sacrificial layers.

11. The method of claim 10, further comprising:
forming liners covering the top semiconductor sacrificial layers prior to replacing the bottom semiconductor sacrificial layers with the dielectric sacrificial layers; and
removing the liners after replacing the bottom semiconductor sacrificial layers with the dielectric sacrificial layers.

12. The method of claim 9, further comprising:
forming first inner spaces on opposite ends of the dielectric sacrificial layers; and
after forming the first inner spaces, forming second inner spaces on opposite ends of the top semiconductor sacrificial layers.

13. The method of claim 9, wherein the dielectric sacrificial layers are made of a silicon-containing dielectric material.

14. The method of claim 9, wherein removing the dielectric sacrificial layers and the top semiconductor sacrificial layers comprises:
performing a first etching process to remove the dielectric sacrificial layers; and
performing a second etching process to remove the top semiconductor sacrificial layers, wherein the first etching process and the second etching process are performed at different time points.

15. The method of claim 14, wherein an etchant of the first etching process is different from an etchant of the second etching process.

16. A semiconductor device, comprising:
a first transistor, comprising:
a first semiconductor channel layer;
first source/drain structures on opposite ends of the first semiconductor channel layer; and
a first gate structure wrapping around the first semiconductor channel layer;
a second transistor stacked above the first transistor and comprising:
a second semiconductor channel layer;
second source/drain structures on opposite ends of the second semiconductor channel layer; and
a second gate structure wrapping around the second semiconductor channel layer;
first inner spacers on opposite sides of a portion of the first gate structure; and
second inner spacers on opposite sides of a portion of the second gate structure, wherein the first inner spacers and the second inner spacers are different in composition.

17. The semiconductor device of claim 16, wherein the first inner spacers include higher oxygen concentration or carbon concentration than the second inner spacers.

18. The semiconductor device of claim 16, wherein the second inner spacers include higher germanium concentration than the first inner spacers.

19. The semiconductor device of claim 16, wherein the second semiconductor channel layer includes higher germanium concentration than the first semiconductor channel layer.

20. The semiconductor device of claim 16, wherein the first inner spacers and the second inner spacers have different widths.
